(19) United States
(12) Patent Application Publication
(10) Pub. No.: US 2010/0078601 A1
(43) Pub. Date: Apr. 1, 2010

(54) Preparation of Lanthanide-Containing Precursors and Deposition of Lanthanide-Containing Films

(75) Inventors: Venkateswara R. PALLEM, Bear (DE); Benjamin J. Feist, Wilmington (DE); Nathan Stafford, Wilmington (DE); Christian Dussarrat, Wilmington (DE)

Correspondence Address: AIR LIQUIDE;Intellectual Property, 2700 POST OAK BOULEVARD, SUITE 1800, HOUSTON, TX, 77056, US

(73) Assignee: American Air Liquide, Inc., Fremont, CA (US)

(21) Appl. No.: 12/414,152

(22) Filed: Mar. 30, 2009

Related U.S. Application Data
(60) Provisional application No. 61/041,124, filed on Mar. 31, 2008.

(51) Int. Cl. H01L 21/3205; C23C 16/44; C23C 16/00; H01B 1/22; C07F 5/00

(52) U.S. Cl. 252/512; 438/680; 427/248.1; 427/255.7; 534/15; 257/E21.294

(57) ABSTRACT

Methods and compositions for depositing rare earth metal-containing layers are described herein. In general, the disclosed methods deposit the precursor compounds comprising rare earth-containing compounds using vapor deposition methods such as chemical vapor deposition or atomic layer deposition. In certain embodiments, the disclosed precursor compounds include a cyclopentadienyl ligand having at least one aliphatic group as a substituent.

### CROSS REFERENCE TO RELATED APPLICATIONS

The present application claims the benefit of U.S. Provisional Application Ser. No. 61/041,124 filed Mar. 31, 2008, herein incorporated by reference in its entirety for all purposes.

### BACKGROUND

One of the serious challenges the industry faces is developing new gate dielectric materials for Dynamic Random Access Memory (DRAM) and capacitors. For decades, silicon dioxide (SiO₂) was a reliable dielectric, but as transistors have continued to shrink and the technology moved from “Full Si” transistor to “Metal Gate/High-k” transistors, the reliability of the SiO₂-based gate dielectric is reaching its physical limits. The need for new high dielectric constant material and processes is increasing and becoming more and more critical as the size for current technology is shrinking. New generations of oxides especially based on lanthanide-containing materials are thought to give significant advantages in capacitance compared to conventional dielectric materials.

Nevertheless, deposition of lanthanide-containing layers is difficult and new material and processes are increasingly needed. For instance, atomic layer deposition (ALD) has been identified as an important thin film growth technique for microelectronics manufacturing, relying on sequential and saturating surface reactions of alternatively applied precursors, separated by inert gas purging. The surface-controlled nature of ALD enables the growth of thin films having high conformality and uniformity with an accurate thickness control. The need to develop new ALD processes for rare earth materials is obvious.

Unfortunately, the successful integration of compounds used for depositions into vapor deposition processes has proven to be difficult. Two classes of molecules are typically proposed: beta-diketonates and cyclopentadienyls. The former family of compounds is stable, but the melting points always exceed 90° C., making them impractical. Lanthanide 2,2-6,6-tetramethylheptanedionate's [La(tmhd)₃] melting point is as high as 260° C., and the related lanthanide 2,2,7-trimethyloctanedionate's [La(tmod)₃] melting point is 197° C. Additionally, the delivery efficiency of beta-diketonates is very difficult to control. Cyclopentadienyls also exhibit low volatility with a high melting point. Molecule design may both help improve volatility and reduce the melting point. However, in process conditions, these classes of materials have been proven to have limited use. For instance, La(iPrCp)₃ does not allow an ALD regime above 225° C.

Some of the lanthanide precursors currently available present many drawbacks when used in a vapor deposition process. For instance, fluorinated lanthanide precursors can generate LnF₃ as a by-product. This by-product is known to be difficult to remove.

Consequently, there exists a need for alternate precursors for deposition of lanthanide containing films.

### SUMMARY

Disclosed are non-limiting embodiments of precursors and methods for depositions of precursors which may be used in the manufacture of semiconductor materials, photovoltaic, LCD-TFT, or flat panel-type devices.

Also disclosed are methods for depositing a film containing lanthanide or mixed lanthanides using the precursors with general molecular formula, Ln(R₁Cp)₂(R₂Cp), where R₁≠R₂. Depositing lanthanide (Y(R₁Cp)₂(R₂CP)) film at temperatures in the range of 250-600° C. at pressures ranging from 0.5 mTorr −20 Torr to deposit films having the general formula LnₙOₘ or LnₓM_{y}O_{z}. Film composition will be dependent on the application.

Also disclosed is a method of forming a lanthanide-containing layer on a substrate. A precursor having formula Ia or Ib:

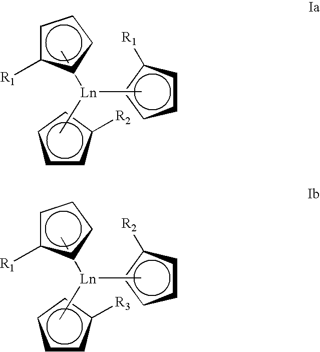

is contacted with a substrate using a vapor deposition process to form a lanthanide-containing layer on the substrate. In formulas Ia and Ib, Ln is selected from the lanthanide group (Ln=Sc, Y, La, Ce, Pr, Nd, Sm, Eu, Gd, Tb, Dy, Ho, Er, Tm, Yb, Lu) and each R₁, R₂, and R₃ is hydrogen or an aliphatic group.

The lanthanide-containing precursor may include either (a) two identical substituted cyclopentadienyl ligands and a third substituted cyclopentadienyl ligand that differs from the first two or (b) three substituted cyclopentadienyl ligands that differ from each other. Either embodiment is designed to reduce the melting point, preferentially to a melting point below 70° C. Preferably, each embodiment provides the lanthanide-containing compound in liquid form at room temperature. Finally, each embodiment provides a lanthanide-containing compound that maintains high thermal stability for use in vapor deposition methods.

Also disclosed is the synthesis of mixed ligand lanthanide precursors derived from substituted cyclopentadienes.

One preferred embodiment of the present invention is synthesizing and using these precursors in a thermal or plasma or remote plasma process in ALD/CVD or pulse CVD mode and in reaction with an oxygen source, preferably O3/O2/H2O/NO/ . . .

Preferred Applications Include but are not Limited to:
Ln₂O₃
(LnLn′)O₃
Ln₂O₃-Ln′₂O₃
LnSiₓO_{y}
(Al, Ga, Mn)LnO₃
HfLnOₓ

Benefits Include:
ALD or CVD of various lanthanide-containing films
Low melting point solids or liquids at room temperature
Increased volatility as compared to the parent homoleptic compounds
Solubility in several solvents

The proposed combination of different substituted cyclopentadieyl ligand systems as anionic ligands bonded to the lanthanide increases the entropy of the resulting lanthanide-containing compounds and thereby dramatically reduces the melting point.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and the specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### Notation and Nomenclature

Certain terms are used throughout the following description and claims to refer to particular chemical constituents.

As used herein, the abbreviation “Ln” refers to the lanthanide group, which includes the following elements: scandium (“Sc”), yttrium (“Y”), lanthanum (“La”), cerium (“Ce”), praseodymium (“Pr”), neodymium (“Nd”), samarium (“Sm”), europium (“Eu”), gadolinium (“Gd”), terbium (“Tb”), dysprosium (“Dy”), holmium (“Ho”), erbium

(“Er”), thulium (“Tm”), ytterbium (“Yb”), or lutetium (“Lu”); the abbreviation “Cp” refers to cyclopentadiene; prime (“′”) is used to indicate a different component than the first, for example (LnLn′)O₃ refers to a lanthanide oxide containing two different lanthanide elements; the term “aliphatic group” refers to a C1-C5 linear or branched chain alkyl group; the term “alkyl group” refers to saturated functional groups containing exclusively carbon and hydrogen atoms; the abbreviation “Me” refers to a methyl group; the abbreviation “Et” refers to an ethyl group; the abbreviation “Pr” refers to a propyl group; and the abbreviation “iPr” refers to an isopropyl group.

### DESCRIPTION OF PREFERRED EMBODIMENTS

Disclosed are precursor compounds having the general formula Ia or Ib:

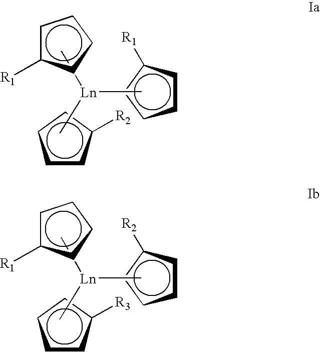

wherein Ln represents the lanthanide group, which includes Sc, Y, La, Ce, Pr, Nd, Sm, Eu, Gd, Tb, Dy, Ho, Er, Tm, Yb, and Lu, R₁, R₂, R₃ are selected from hydrogen and a C1-C5 linear or branched alkyl group, R₁≠R₂≠H, and R₁≠R₂≠R₃.

The synthesis of Ln(R₁Cp)₂(R₂Cp) precursors can be carried out by reacting Ln(R₁Cp)₂Cl with R₂CpM (where M=Li, Na, K). The synthesis of Ln(R₁Cp)(R₂Cp)(R₃Cp) precursors can be carried out either in-situ reacting LnX₃ (where X=Cl, Br, I) in a stepwise addition of RₓCpM (where Rₓ=R₁, R₂, R₃ and M=Li, Na, K) or isolating intermediate products Ln(R₁Cp)X₂ or Ln(R₁Cp)(R₂Cp)X and by successive addition reactions with R₂CpM or R₃CpM. The precursor can be delivered in neat form or in a blend with a suitable solvent, preferably ethyl benzene, xylenes, mesitylene, decane, dodecane in different concentrations.

The disclosed precursor compounds (hereinafter the “lanthanide-containing precursor”) may be deposited to form lanthanide films using any deposition methods known to those of skill in the art. Examples of suitable deposition methods include without limitation, conventional CVD, low pressure chemical vapor deposition (LPCVD), atomic layer deposition (ALD), pulsed chemical vapor deposition (P-CVD), plasma enhanced atomic layer deposition (PE-ALD), or combinations thereof. In an embodiment, the lanthanide-containing precursor may be introduced into a reaction chamber. The reaction chamber may be any enclosure or chamber within a device in which deposition methods take place such as without limitation, a cold-wall type reactor, a hot-wall type reactor, a single-wafer reactor, a multi-wafer reactor, or other types of deposition systems under conditions suitable to cause the precursors to react and form the layers. The lanthanide-containing precursor may be introduced into the reaction chamber by bubbling an inert gas (e.g. N₂, He, Ar, etc.) into the lanthanide-containing precursor and providing the inert gas plus the lanthanide-containing precursor mixture to the reactor.

Generally, the reaction chamber contains one or more substrates on to which lanthanide-containing layers or films will be deposited. The one or more substrates may be any suitable substrate used in the manufacture of semiconductors, photovoltaics, LCD-TFT, or flat panel-type devices. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium or gold) may be used.

The method of depositing a lanthanide-containing film on a substrate may further comprise introducing a second precursor different from the lanthanide-containing precursor into the reaction chamber. For example, the second precursor may include, without limitation, Ti, Ta, Bi, Hf, Zr, Pb, Nb, Mg, Al, Sr, Y, Ba, Ca, Ln, or combinations thereof. The second precursor is directed to the substrate to deposit at least part of the second precursor to form a lanthanide-containing film on the one or more substrates.

In embodiments, the reaction chamber may be maintained at a pressure ranging from about 0.5 mTorr to about 20 Torr. In addition, the temperature within the reaction chamber may range from about 250° C. to about 600° C. In some embodiments, the lanthanide-containing precursor is a liquid at room temperature. Preferably, the lanthanide-containing precursor has a melting point lower than about 70° C.

Furthermore, the deposition of the lanthanide-containing film may take place in the presence of at least one reaction fluid, wherein said reaction fluid is an oxygen-containing fluid. Thus, an oxygen-containing fluid may be introduced into the reaction chamber. The oxygen-containing fluid may be a fluid or a gas. The oxygen-containing fluid may react with the lanthanide-containing precursor. Examples of suitable oxygen-containing fluids include, without limitation, O₂, O₃, H₂O, H₂O₂, acetic acid, formalin, para-formaldehyde, and combinations thereof.

The lanthanide-containing precursor and the reaction fluid may be introduced sequentially (as in ALD) or simultaneously (as in CVD) to the reaction chamber. In one embodiment, the lanthanide-containing precursor and second precursor, or the lanthanide-containing precursor and the reaction fluid, may be pulsed sequentially or simultaneously (e.g. pulsed CVD) into the reaction chamber. Each pulse of the second and/or lanthanide-containing precursor may last for a time period ranging from about 0.01 s to about 10 s, alternatively from about 0.3 s to about 3 s, alternatively from about 0.5 s to about 2 s. In another embodiment, the reaction fluid may also be pulsed into the reaction chamber. In such embodiments, the pulse of each fluid may last for a time period ranging from about 0.01 s to about 10 s, alternatively from about 0.3 s to about 3 s, alternatively from about 0.5 s to about 2 s.

The resulting lanthanide films or lanthanide-containing layers may include Ln₂O₃, (LnLn′)O₃, Ln₂O₃-Ln′₂O₃, LnSiₓO_{y}, (Al, Ga, Mn)LnO₃, or HfLnOₓ.

### EXAMPLES

The following non-limiting examples are provided to further illustrate embodiments of the invention. However, the examples are not intended to be all inclusive and are not intended to limit the scope of the inventions described herein. The following examples illustrate possible synthesis methods, according to embodiments of the current invention.

### Example 1

A 100 mL Schlenk flask was charged with Lal₃ (5.00 g, 9.62 mmol) and tetrahydrofuran (THF) (30 mL) inside a glove box. The mixture was stirred at room temperature for 30 minutes. Na(iPrCp) (2.50 g, 19.25 mmol) was added to this suspension in small portions as a powder at room temperature. The mixture was stirred at room temperature for 1 hour. Na(Me₅Cp) (19.25 mL of 0.5 M solution in THF, 9.62 mmol) was added to the stirred reaction mixture. The mixture was stirred at room temperature for 16 hours. The solvent was removed from the mixture under vacuum leaving a brown solid residue that was then dried under vacuum at 70° C. for 1 hour. Toluene (50 mL) was added to the dried residue by stainless steel canula transfer. The mixture was stirred at room temperature for 16 hours and filtered through a Celite filter. The solids on the filter were washed with toluene and the washes were combined with the filtrate. The solvents were removed from the filtrate under vacuum leaving a brown solid residue that was dried under vacuum at 70° C. for 2 hours. The crude product was sublimed under 6-10 mtorr at 130-180° C. to give 3.7 g (79% yield) of a slightly yellow crystalline solid. A small amount of the impurity La(iPrCp)₃ was detected in the sublimed material by NMR. A pure sample of the yellowish product, La(iPrCp)₂(Me₅Cp), was obtained by recrystallization from pentane at −30° C. A proton NMR analysis of the product in benzene (¹H NMR (C₆D₆)) provided five peaks as follows: δ 1.08 (d, 12 H, Me₂CH), 1.98 (s, 15 H, Me₅Cp), 2.79 (sept, 2 H, Me₂CH), 5.94 (t, 4 H, iPrC₅H₄), 6.10 (t, 4 H, iPrC₅H₄).

### Example 2

A 250 mL Schlenk flask equipped with a magnetic stir bar was charged with Lal₃ (10.36 g, 19.94 mmol) and THF (100 mL) inside the glove box. The mixture was stirred at room temperature for 1 hour. Na(iPrCp) (5.19 g, 39.88 mmol) was added to this suspension in small portions as a powder at room temperature. The mixture was stirred at room temperature for 1 hour. K(iPr₃Cp) (4.59 g, 19.94 mmol) was added to the stirred reaction mixture in small portions as a powder at room temperature. The mixture was stirred at room temperature for 16 hours. The solvent was removed from the mixture under vacuum leaving a brown oil and solids. Toluene (50 mL) was added to the residue. A brown solution and white precipitate were obtained. The mixture was stirred at room temperature for 16 hours and filtered through a Celite filter. The solids on the filter were washed with toluene and the washes were combined with the filtrate. The solvent was removed from the filtrate under vacuum leaving a viscous brown oil that was distilled under 40 mtorr at 200° C. (oil bath temperature) to give 8.6 g (79% yield) of a slightly yellow viscous liquid. ¹H NMR spectrum of the distillate showed that it was a 70:30 (mol) mixture of the product, La(iPrCp)₂(iPr₃Cp), and La(iPrCp)₃. A proton NMR analysis of the product in benzene (¹H NMR (C₆D₆)) provided 5 peaks as follows: δ 1.08-1.21 (m, 30 H, Me₂CH), 2.71-2.99 (m, 5 H, Me₂CH), 5.91 (s, 2 H, iPr₃C₅H₂), 6.07 (t, 4 H, iPrC₅H₄), 6.17 (t, 4 H, iPrC₅H₄).

While embodiments of this invention have been shown and described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

1. A method for depositing a lanthanide film on a semiconductor substrate, comprising:
a) providing a substrate;
b) providing a precursor of the general formula Ln(R¹Cp)₂(R²Cp), where R¹≠R²≠H, or Ln(R¹Cp)(R²Cp)(R³Cp), where R¹≠R²≠R³, wherein each R is selected from H or a C1-C5 alkyl chain; and
c) depositing a lanthanide film on the substrate.

2. The method of claim 1, further comprising depositing the lanthanide film on the substrate at a temperature between about 250° C. and about 600° C.

3. The method of claim 1, further comprising depositing the lanthanide film on the substrate at a pressure between about 0.5 mTorr and about 20 Torr.

4. The method of claim 1, wherein the precursor is a liquid at room temperature.

5. The method of claim 1, wherein the lanthanide film is selected from the group consisting of Ln₂O₃, (LnLn′)O₃, Ln₂O₃-Ln′₂O₃, LnSiₓO_{y}, (Al, Ga, Mn)LnO₃, and HfLnOₓ.

6. A method of forming a lanthanide-containing layer on a substrate, the method comprising: providing a reactor having at least one substrate disposed therein; introducing at least one lanthanide-containing precursor into the reactor, wherein the lanthanide-containing precursor has the general formula Ia or Ib: 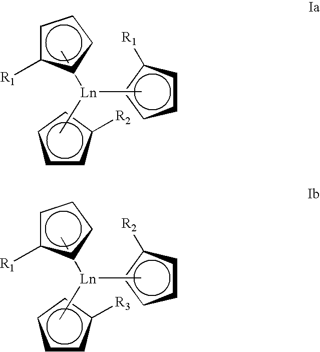
wherein Ln is selected from the lanthanide group, each R¹, R², R³ is independently hydrogen or a C1-C5 aliphatic group, R¹≠R²≠H, and R¹≠R²≠R³; and contacting the lanthanide-containing precursor and the substrate to form a lanthanide-containing layer on at least one surface of the substrate using a deposition process.

7. The method of claim 6, further comprising introducing a second precursor into the reactor, wherein the second precursor is different than the lanthanide-containing precursor and depositing at least part of the second precursor to form the lanthanide-containing layer on the one or more substrates.

8. The method of claim 7 wherein the second precursor comprises a member selected from the group consisting of Ti, Ta, Bi, Hf, Zr, Pb, Nb, Mg, Al, Sr, Y, Ba, Ca, a lanthanide, and combinations thereof.

9. The method of claim 6, further comprising:
a) providing at least one reaction fluid into the reactor, wherein said reaction fluid is an oxygen containing fluid; and
b) reacting said lanthanide-containing precursor with said reaction fluid.

10. The method of claim 9, wherein the at least one reaction fluid is selected from the group consisting of O₂, O₃, H₂O, H₂O₂, acetic acid, formalin, para-formaldehyde, and combinations thereof.

11. The method of claim 9, wherein the lanthanide-containing precursor and the reaction fluid are either introduced at least partially simultaneously as in a chemical vapor deposition process, or are introduced at least partially sequentially as in an atomic layer deposition process.

12. The method of claim 6, wherein the deposition process is a chemical vapor deposition process.

13. The method of claim 6, wherein the deposition process is an atomic layer deposition process having a plurality of deposition cycles.

14. A lanthanide film coated substrate comprising the product of the method of claim 6.

15. A new composition comprising a lanthanide-containing precursor with the general formula: 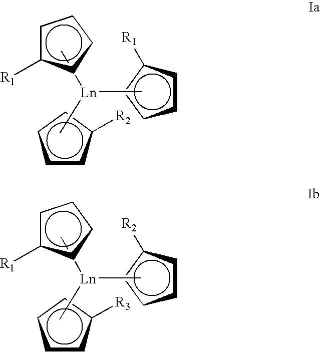
wherein:
Ln is a lanthanide;
R¹, R², R³ are selected from H and a C1-C5 linear or branched alkyl group;
R¹≠R²≠R³; and
the precursor has a melting point lower than about 70° C.

16. The composition of claim 15, wherein the lanthanide-containing precursor is a liquid at room temperature.

17. A method of making a mixed ligand lanthanide precursor derived from substituted cyclopentadienes comprising reacting LnX₃ with RₓCpM by a stepwise addition reaction, wherein Ln is selected from the lanthanide group, X=Cl, Br, or I, Rₓ=R¹, R², or R³, each R¹, R², R³ is independently hydrogen or a C1-C5 aliphatic group, R¹≠R²≠H, R¹≠R²≠R³, and M=Li, Na, or K.

18. The method of claim 17, wherein the mixed ligand lanthanide precursor derived from substituted cyclopentadienes comprises Ln(R¹Cp)₂(R²Cp).

19. The method of claim 17, wherein the mixed ligand lanthanide precursor derived from substituted cyclopentadienes comprises Ln(R¹Cp)(R²Cp)(R³Cp).

20. The method of claim 17, wherein the stepwise addition reaction occurs in-situ.

21. The method of claim 1, wherein the precursor has the general formula Ln(R¹ₚCp)₂(R²_{q}Cp) or Ln(R¹ₚCp)(R²_{q}Cp)(R³ᵣCp) and 1≦p, q, r≦5.

22. The method of claim 21, wherein Ln is selected from the group consisting La, Ce, and Pr.

23. The method of claim 22, wherein the precursor has the general formula Ln(EtCp)2(iPr₃Cp).

24. The method of claim 22, wherein the precursor has the general formula Ln(iPrCp)₂(iPr₃Cp).

25. The method of claim 6, wherein the lanthanide-containing precursor has the general formula Ln(R¹ₚCp)₂(R²_{q}Cp) or Ln(R¹ₚCp)(R²_{q}Cp)(R³ᵣCp) wherein 1≦p, q, r≦5.

26. The method of claim 25, wherein Ln is selected from the group consisting La, Ce, and Pr.

27. The method of claim 26, wherein the lanthanide-containing precursor has the general formula Ln(EtCp)₂(iPr₃Cp).

28. The method of claim 26, wherein the lanthanide-containing precursor has the general formula Ln(iPrCp)₂(iPr₃Cp).

29. The composition of claim 15, wherein the lanthanide-containing precursor has the general formula Ln(R¹ₚCp)₂(R²_{q}Cp) or Ln(R¹ₚCp)(R²_{q}Cp)(R³ᵣCp) and 1≦p, q, r≦5.

30. The composition of claim 29, wherein Ln is selected from the group consisting La, Ce, and Pr.

31. The composition of claim 30, wherein the lanthanide-containing precursor has the general formula Ln(EtCp)₂(iPr₃Cp).

32. The composition of claim 30, wherein the lanthanide-containing precursor has the general formula Ln(iPrCp)₂(iPr₃Cp).

33. The method of claim 17, wherein Rₓ=R¹ₚ, R²_{q}, or R³ᵣ and 1≦p, q, r≦5.

34. The method of claim 33, wherein Ln is selected from the group consisting La, Ce, and Pr.

35. The method of claim 34, wherein the mixed ligand lanthanide precursor derived from substituted cyclopentadienes has the general formula Ln(EtCp)₂(iPr₃Cp).

36. The method of claim 34, wherein the mixed ligand lanthanide precursor derived from substituted cyclopentadienes has the general formula Ln(iPrCp)₂(iPr₃Cp).
